(19) United States
(12) Patent Application Publication
(10) Pub. No.: US 2024/0112720 A1
(43) Pub. Date: Apr. 4, 2024

(54) UNMATCHED CLOCK FOR COMMAND-ADDRESS AND DATA

(71) Applicant: Advanced Micro Devices, Inc., Santa Clara, CA (US)

(72) Inventors: Aaron D Willey, Hayward, CA (US); Karthik Gopalakrishnan, Cupertino, CA (US); Pradeep Jayaraman, San Jose, CA (US)

(73) Assignee: Advanced Micro Devices, Inc., Santa Clara, CA (US)

(21) Appl. No.: 17/957,788

(22) Filed: Sep. 30, 2022

(51) Int. Cl. G11C 11/4076

(52) U.S. Cl. CPC G11C 11/4076

(57) ABSTRACT

A memory system includes a PHY embodied on an integrated circuit, the PHY coupling to a memory over conductive traces on a substrate. The PHY includes a reference clock generation circuit providing a reference clock signal to the memory, a first group of driver circuits providing CA signals to the memory, and a second group of driver circuits providing DQ signals to the memory. A plurality of the conductive traces which carry the DQ signals are constructed with a length longer than that of conductive traces carrying the reference clock signal in order to reduce an effective insertion delay associated with coupling the reference clock signal to latch respective incoming DQ signals.

### BACKGROUND

Modern dynamic random-access memory (DRAM) provides high memory bandwidth by increasing the speed of data transmission on the bus connecting the DRAM and one or more data processors, such as graphics processing units (GPUs), central processing units (CPUs), and the like. In one example, graphics double data rate (GDDR) memory has pushed the boundaries of data transmission rates to accommodate the high bandwidth needed for graphics applications. In order to ensure the correct reception of data, modern GDDR memories have required extensive training prior to operation to make sure that the receiving circuit can correctly capture the data.

Another issue that effects correct capture of data is clock jitter, which includes random and deterministic variations in the period and duty cycle of the clock signal which clocks or latches transmitters and receivers on a communication link. Clock jitter contributes to the probability that even a correctly trained link may sample a signal incorrectly, causing a bit error.

### BRIEF DESCRIPTION OF THE DRAWINGS

FIG. 1 illustrates in block diagram form a data processing system according to some embodiments;

FIG. 2 illustrates in block diagram form a GDDR PHY-DRAM link of the data processing system of FIG. 1 according to some embodiments;

FIG. 3 illustrates in block diagram form a printed circuit board (PCB) according to some embodiments; and

FIG. 4 illustrates in diagram form a number of transmission delays associated with the PCB of FIG. 3.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

A data processing system includes a data processor integrated circuit (IC) coupled to a substrate. The IC has a physical layer circuit (PHY) for coupling to a memory over conductive traces on the substrate. The PHY includes a reference clock generation circuit providing a reference clock signal to the memory, a first group of driver circuits providing command/address (CA) signals to the memory, and a second group of driver circuits providing data (DQ) signals to the memory. A plurality of the conductive traces which carry the and DQ signals are constructed with a length longer than that of conductive traces carrying the reference clock signal in order to reduce an effective insertion delay associated with coupling the reference clock signal to latch respective incoming DQ signals at the memory.

A method for signaling between a physical layer (PHY) circuit and a memory, includes driving CA signals to the memory over a first group of conductive traces on a substrate. The method includes driving DQ signals to the memory over a second group of conductive traces on the substrate. A reference clock signal is provided to the memory over at least one additional conductive trace on the substrate having an associated propagation delay shorter than that of the second group of conductive traces in order to reduce an effective insertion delay associated with coupling the reference clock signal to latch respective incoming DQ signals.

A memory system includes a PHY embodied on an integrated circuit, the PHY coupling to a memory over conductive traces on a substrate. The PHY includes a reference clock generation circuit providing a reference clock signal to the memory, a first group of driver circuits providing CA signals to the memory, and a second group of driver circuits providing DQ signals to the memory. A plurality of the conductive traces which carry the DQ signals are constructed with a length longer than that of conductive traces carrying the reference clock signal in order to reduce an effective insertion delay associated with coupling the reference clock signal to latch respective incoming DQ signals.

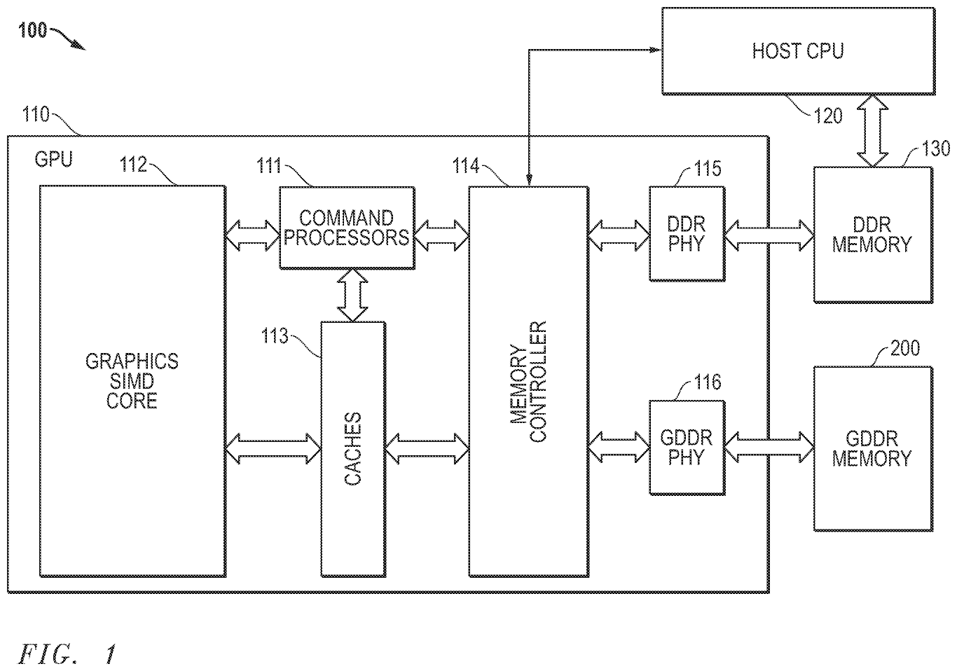

FIG. 1 illustrates in block diagram for a data processing system 100 according to some embodiments. Data processing system 100 includes generally a data processor in the form of a graphics processing unit (GPU) 110, a host central processing unit (CPU) 120, a double data rate (DDR) memory 130, and a graphics DDR (GDDR) memory 140.

GPU 110 is a discrete graphics processor that has extremely high performance for optimized graphics processing, rendering, and display, but requires a high memory bandwidth for performing these tasks. GPU 110 includes generally a set of command processors 111, a graphics single instruction, multiple data (SIMD) core 112, a set of caches 113, a memory controller 114, a DDR physical interface circuit (PHY) 115, and a GDDR PHY 116.

Command processors 111 are used to interpret high-level graphics instructions such as those specified in the OpenGL programming language. Command processors 111 have a bidirectional connection to memory controller 114 for receiving the high-level graphics instructions, a bidirectional connection to caches 113, and a bidirectional connection to graphics SIMD core 112. In response to receiving the high-level instructions, command processors 111 issue SIMD instructions for rendering, geometric processing, shading, and rasterizing of data, such as frame data, using caches 113 as temporary storage. In response to the graphics instructions, graphics SIMD core 112 executes the low-level instructions on a large data set in a massively parallel fashion. Command processors 111 use caches 113 for temporary storage of input data and output (e.g., rendered and rasterized) data. Caches 113 also have a bidirectional connection to graphics SIMD core 112, and a bidirectional connection to memory controller 114.

Memory controller 114 has a first upstream port connected to command processors 111, a second upstream port connected to caches 113, a first downstream bidirectional port, and a second downstream bidirectional port. As used herein, “upstream” ports are on a side of a circuit toward a data processor and away from a memory, and “downstream” ports are on a side if the circuit away from the data processor and toward a memory. Memory controller 114 controls the timing and sequencing of data transfers to and from DDR memory 130 and GDDR memory 140. DDR and GDDR memory support asymmetric accesses, that is, accesses to open pages in the memory are faster than accesses to closed pages. Memory controller 114 stores memory access commands and processes them out-of-order for efficiency by, e.g., favoring accesses to open pages, disfavoring frequent bus turnarounds from write to read and vice versa, while observing certain quality-of-service objectives.

DDR PHY 115 has an upstream port connected to the first downstream port of memory controller 114, and a downstream port bidirectionally connected to DDR memory 130. DDR PHY 115 meets all specified timing parameters of the implemented version or versions of DDR memory 130, such as DDR version five (DDRS), and performs training operations at the direction of memory controller 114. Likewise, GDDR PHY 116 has an upstream port connected to the second downstream port of memory controller 114, and a downstream port bidirectionally connected to GDDR memory 200. GDDR PHY 116 meets all specified timing parameters of the implemented version of GDDR memory 140, such as GDDR version seven (GDDR7), and performs training operations at the direction of memory controller 114, including initial training of the various data and command lanes of GDDR PHY 116, and retraining during operation.

In operation, data processing system can be used as a graphics card or accelerator because of the high bandwidth graphics processing performed by graphics SIMD core 112. Host CPU 120, running an operating system or an application program, sends graphics processing commands to CPU 110 through DDR memory 130, which serves as a unified memory for GPU 110 and host CPU 120. It may send the commands using, for example, as OpenGL commands, or through any other host CPU to GPU interface. OpenGL was developed by the Khronos Group, and is a cross-language, cross-platform application programming interface for rendering 2D and 3D vector graphics. Host CPU 120 uses an application programming interface (API) to interact with GPU 110 to provide hardware-accelerated rendering.

Data processing system 100 uses two types of memory. The first type of memory is DDR memory 130, and is accessible by both GPU 110 and host CPU 120. As part of the high performance of graphics SIMD core 112, GPU 110 uses a high-speed graphics double data rate (GDDR) memory. For example, the new graphics double data rate, version seven (GDDR7) memory will be able to achieve very high link speeds and 24-40 gigabits per second (Gbps) per-pin bandwidth. Because of the high bandwidth, GDDR7 is suitable for very high-performance graphics operations.

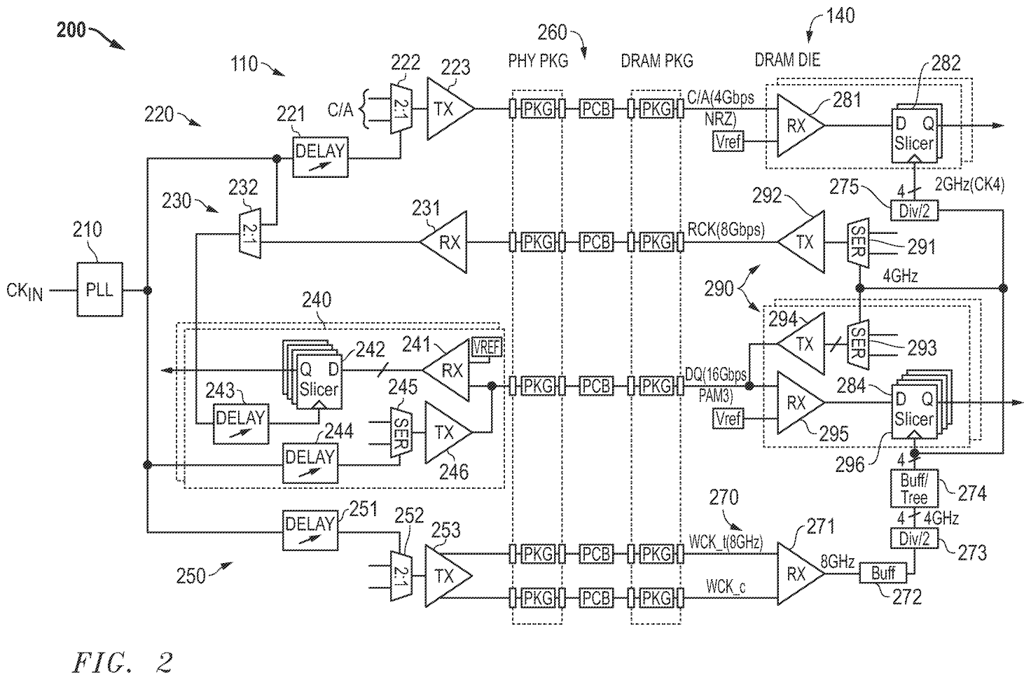

FIG. 2 illustrates in block diagram form a GDDR PHY-DRAM link 200 of data processing system 100 of FIG. 1 according to some embodiments. GDDR PHY-DRAM link 200 includes portions of GPU 110 and GDDR memory 140 that communicate over a physical interface 260.

GPU 110 includes a phase locked loop (PLL) 210, a command and address (“C/A”) circuit 220, a read clock circuit 230, a data circuit 240, and a write clock circuit 250. These circuits form part of GDDR PHY 118 of GPU 110.

Phase locked loop 210 operates as a reference clock generation circuit and has an input for receiving an input clock signal labelled “CKIN”, and an output.

C/A circuit 220 includes a delay element 221, a selector 222, and a transmit buffer 223 labelled “TX”. Delay element 221 has an input connected to the output of PLL 210, and an output, and has a variable delay controlled by an input, not specifically shown in FIG. 2. The variable delay is determined at startup by calibration controller 115 and adjusted during operation by compensation circuit 116 according to the techniques described herein. Selector 222 has a first input for receiving a first command/address value, a second input for receiving a second command/address value, and a control input connected to the output of delay element 221. Transmitter 223 has an input connected to the output of selector 222, and an output connected to a corresponding integrated circuit terminal for providing a command/address signal labelled “C/A” thereto. Note that C/A circuit 220 includes a set of individual buffers for each signal in the C/A signal group that are constructed the same as the representative selector 222 and buffer 223 shown in FIG. 2, but only a representative C/A circuit 220 is shown.

Read clock circuit 230 include a receive buffer 231 labelled “RX”, and a selector 232. Receive buffer 231 has an input connected to a corresponding integrated circuit terminal for receiving a signal labelled “RCK”, and an output. Receive clock selector 232 has a first input for connected to the output of PLL 210, a second input connected to the output of receive buffer 231, an output, and a control input for receiving a mode signal, not shown in FIG. 2.

Data circuit 240 includes a receive buffer 241, a latch 242, delay elements 243 and 244, a serializer 245, and a transmit buffer 246. Receive buffer 241 has a first input connected to an integrated circuit terminal that receives a data signal labelled generically as “DQ”, a second input for receiving a reference voltage labelled “V_{REF}”, and an output. Latch 242 is a D-type latch having an input labelled “D” connected to the output of receive buffer 241, a clock input, and an output labelled “Q” for providing an output data signal. The interface between GDDR PHY 118 and GDDR memory 140 implements a three-level, pulse amplitude modulation data signaling system known as “PAM-3”, which encodes data bits into one of three nominal voltage levels. In other embodiments, other PAM schemes are employed, such as PAM-4, for example. Receive buffer 241 discriminates which of the three levels is indicated by the input voltage, and outputs two data bits to represent the state in response. For example, receive buffer 241 could generate two slicing levels based on V_{REF} defining three ranges of voltages, and use two comparators to determine which range the received data signal falls in. Data circuit 240 includes latches which latch the data bits and is replicated for each bit position. Delay element 243 has an input connected to the output of selector 232, and an output connected to the clock input of latch 242. Delay element 244 has an input connected to the output of PLL 210, and an output. Serializer 245 has inputs for receiving a first data value of a given bit position and a second data value of the given bit position, the first and second data values corresponding to sequential cycles of a burst, a control input connected to the output of delay element 244, and an output connected to the corresponding DR terminal. Each data byte of the data bus has a set of data circuits like data circuit 240 for each bit of the byte. This replication allows different data bytes that have different routing on the printed circuit board to have different delay values.

Write clock circuit 250 includes a delay element 251, a selector 252, and a transmit buffer 253. Delay element 251 has an input connected to the output of PLL 210, and an output. Selector 252 has a first input for receiving a first clock state signal, a second input for receiving a second clock voltage, a control input connected to the output of delay element 251, and an output. Transmit buffer 253 has an input connected to the output of selector 252, and an output a first output connected to a corresponding integrated circuit terminal for providing a true write clock signal labelled “WCK_t” thereto, and a second output connected to a corresponding integrated circuit terminal for providing a complement write clock signal labelled “WCK_c” thereto.

GDDR memory 140 includes generally a write clock receiver 270, a command/address receiver 280, and a data path transceiver 290. Write clock receiver 270 includes a receive buffer 271, a buffer 272, a divider 273, a buffer/tree 274, and a divider 275. Receive buffer 271 has a first input connected to an integrated circuit terminal of GDDR memory 140 that receives the WCK_t signal, a second input connected to an integrated circuit terminal of GDDR memory 140 that receives the WCK_c signal, and an output. In the example shown in FIG. 2, the output of receive buffer 271 is clock signal having a nominal frequency of 8 GHz. Buffer 272 has an input connected to the output of receive buffer 271, and an output. Divider 273 has an input connected the output of buffer 272, and an output for providing a divided clock having a nominal frequency of 4 GHz. Divider 275 has an input for connected to the output of buffer/tree 274, and an output for providing a clock signal labelled “CK4” having a nominal frequency of 2 GHz.

Command/address receiver 280 includes a receive buffer 281 and a slicer 282. Receive buffer 281 has a first input connected to a corresponding integrated circuit terminal of GDDR memory 140 that receives the C/A signal, a second input for receiving V_{REF}, and an output. The C/A input signal is received as a normal binary signal having two logic states levels and is considered a non-return-to-zero (NRZ) signal encoding. Slicer 282 has a set of two data latches each having a D input connected to the output of receive buffer 281, a clock input for receiving a corresponding one of the output of divider 275, and a Q output for providing a corresponding C/A signal.

Data path transceiver 290 includes a serializer 291, a transmitter 292, a serializer 293, a transmitter 294, a receive buffer 295, and a slicer 296. Serializer 291 has an input for receiving a first read clock level, a second input for receiving a second read clock level, a select input connected to the output of buffer/tree 274, and an output. Transmitter 292 has an input connected to the output of serializer 293, and an output connected to the RCK terminal of GDDR memory 140. Serializer 293 has an input for receiving a first read data value, a second input for receiving a second data value, a select input connected to the output of buffer/tree 274, and an output connected to the DQ terminal of GDDR memory 140. Transmitter 294 has an input connected to the output of serializer 293, and an output connected to the corresponding DQ terminal of GDDR memory 140. Receive buffer 295 has a first input connected to the corresponding DQ terminal of GDDR memory 140, a second input for receiving the V_{REF} value, and an output. Slicer 296 has a set of four data latches each having a D input connected to the output of receive buffer 295, a clock input connected to the output of buffer/tree 274, and a Q output for providing a corresponding DQ signal.

Interface 260 includes a set of physical connections that are routed between a bond pad of the GPU 110 die, through a package impedance to a package terminal, through a trace on a printed circuit board, to a package terminal of GDDR memory 140, through a package impedance, and to a bond pad of the GDDR memory 140 die.

The WCK clock signal exhibits variations in its periodic signal known as jitter. Such random variations are caused by power supply noise on the WCK's PLL, and other random and deterministic factors. The total jitter along any particular clocking path, such as, for example, the paths to the CA and DQ buffers, is known as accumulated jitter. Generally, the DRAM memory has specifications limiting accumulated jitter and n-cycle accumulated jitter, that is the accumulated jitter measured over a number of unit intervals (UIs) of WCK.

The WCK clock signal is divided and distributed through buffer/tree 274 to slicers 296 for clocking incoming DQ signals, and distributed to slicers 282 for clocking incoming CA signals. The various buffers and slicers of FIG. 2 are located on the DRAM die close to their respective input pads, and the on-die path lengths for the DQ signals are matched to each other, as are those of the CA signals. The WCK signal, however, is distributed from its input pad to the various receiver slicers over routes of unmatched length, creating an insertion delay different for each receiver.

The insertion delay of the WCK signal generally increases the n-cycle accumulated jitter at each respective receiver, especially those with the longest on-die signal route. In order to help reduce the n-cycle accumulated jitter, the path length on the PCB is adjusted as further described below.

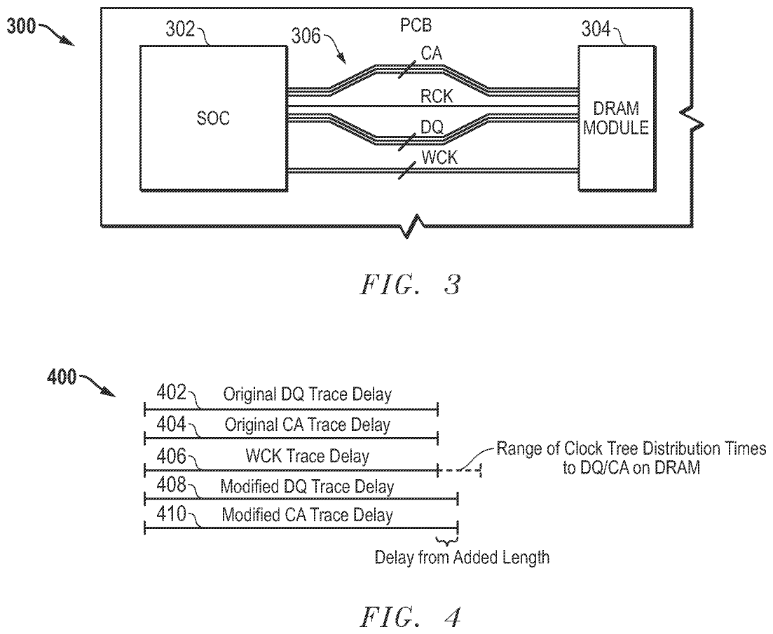

FIG. 3 illustrates in block diagram form a populated printed circuit board (PCB) 300 according to some embodiments. PCB 300 is suitable for implementing data processing system 100 or other data processing systems employing a DRAM module. For example, PCB 300 may embody graphics card PCB, or an APU, sever, or personal computer PCB. PCB 300 includes a system-on-chip (SOC) 302, a DRAM module 304, and a number of PCB traces 306 for implementing a GDDR PHY-DRAM link. Various other integrated circuits, components, and conductive traces are also present to realize a functioning data processing system but are not shown in order to avoid obscuring the relevant portions.

SOC 302 is an integrated circuit mounted along a side of PCB 300 with a socket or by soldering, and generally may be any type of data processing SOC that includes a DDR or GDDR PHY circuit, such as, for example GPU 110 or host CPU 120 of FIG. 1. DRAM module 304 may be a DIMM or other type of memory module. In this implementation, DRAM module 304 is a GDDR DIMM like that of FIG. 2, mounted to PCB 300 with a socket. In other embodiments, other mounting arrangements can be used to communicatively couple DRAM SOC 302 to DRAM module 304.

PCB traces 306 include conductive traces for implementing a physical interface connecting SOC 302 to DRAM module 304, such as physical interface 260 (FIG. 2), and generally embody the “PCB” portion of a physical interface like that shown in FIG. 2. PCB traces 306 include a plurality of command/address traces labelled “CA”, a read clock trace labelled “RCK”, a plurality of data traces labelled “DQ”, and a pair of write clock traces labelled “WCK”. In some implementations there are two RCK traces to carry a differential RCK signal. PCB traces 306 may be implemented on any suitable layer of PCB 300. While a PCB is shown in this implementation, other substrates for holding and conductively coupling integrated circuits may employ the techniques herein.

PCB traces 306 are depicted in an idealized form to illustrate the routing differences among signals. Generally, as depicted by the idealized straight lines for the WCK traces and the circuitous lines for the CA and DQ traces, the plurality of the PCB traces 306 which carry the CA signals and DQ SIGNALS are constructed with a length longer than that of PCB traces 306 carrying the WCK signal in order to reduce an effective insertion delay associated with coupling the reference clock signal to latch respective incoming CA and DQ signals at DRAM module 304. Generally, the plurality of the conductive traces which carry the CA signals and DQ signals are constructed to be longer than a potential shortest length path available for their routing along the substrate.

Preferably, the longer length is sufficient to reduce the effective insertion delay at least 50 picoseconds as compared to an equal length, and more preferably around 100 picoseconds. Generally, a jitter weighing function (JWF) describing the effects of insertion delay on accumulated jitter is given by Equation [1] below:

JWF=4 sin²(πFt) [1]

“F” is the clock frequency and “t” is the insertion delay. Reducing t generally helps reduce the n-cycle accumulated jitter associated with the reference clock signal for all of the plurality of CA and DQ receivers at the memory. For example, reducing t by 50% yields a −6 dB improvement in the JWF.

Concerning the length of the route, for a PCB trace the plurality of the conductive traces carrying the CA signals and DQ signals are at least 12 mm longer than the conductive traces carrying the reference clock signal, and more preferably around 24 mm longer. The reduction in insertion delay generally has a goal of reducing n-cycle accumulated jitter, which helps to meet specifications for the GDDR DRAM PHY including accumulated jitter and n-cycle accumulated jitter for values of n up to a designated number. For example, in in some embodiments, the insertion delay reduction is designed to reduce n-cycle accumulated jitter for n of up to 40, or a specific n value less than 40, for example 30, 20, or 10.

In this implementation, a similar relationship exists between the DQ traces and the RCK trace or traces, where jitter on RCK affects the receivers at the SOC's PHY. The memory includes a read clock driver (e.g., transmitter 292, FIG. 2) providing a read clock signal RCK to the data processor IC. The RCK signal can be single-ended or differential. The lengths of the one or two conductive traces carrying the read clock signal are made shorter than that of conductive traces carrying the DQ signals to provide a similar insertion delay adjustment for the RCK signal.

FIG. 4 shows a diagram 400 depicting a number of transmission delays associated with the PCB of FIG. 3. Diagram 400 depicts the relative propagation delays through the signals' respective PCB traces on a horizontal time scale, and includes an original DQ trace delay 402, and original CA trace delay 406, a WCK trace delay 408, a modified DQ trace delay 410 and a modified CA trace delay 412.

The original DQ and CA trace delays 402 and 404 generally represent the length of a shortest available path or optimal path typically achieved by PCB trace layout methodology. Generally, the individual DQ and CA PCB traces are designed to the be the same length, and so a single delay is shown. These original delays are shown in order to illustrate the design process, and are not present in the PCB of FIG. 3.

While the PCB trace lengths are generally similar, the additional insertion delay due to added route lengths in the DRAM is not identical for each DQ and CA receiver. This variable insertion delay is depicted on WCK trace delay 406 as a dotted portion showing the range of clock tree distribution times to the DQ and CA receivers on the DRAM die. In particular, the DQ lines are more sensitive to jitter because of the double data rate clocking at the WCK clock rate. In some embodiments, the modified trace length has a delay increase that makes the total delay for the WCK distribution the same as the delay for the DQ traces at the DQ receiver that has the average added additional insertion delay among the DQ lines. That is, the WCK signal path is adjusted to such that a WCK clock edge arrives, on average, at the DQ receiver in the middle of the arrival of the data signal edge. In some embodiments, such an average delay arrangement is made for all of the DQ and CA signal.

Thus, a system, a method, and a PCB design have been described for helping mitigate accumulated jitter and n-cycle accumulated jitter. These techniques have the advantage of reducing jitter and improving performance of the DRAM and its ability to meet jitter specifications in the relevant DDR and GDDR standards, or other memory standards.

A data processing system or portions thereof described herein can be embodied one or more integrated circuits, any of which may be described or represented by a computer accessible data structure in the form of a database or other data structure which can be read by a program and used, directly or indirectly, to fabricate integrated circuits. For example, this data structure may be a behavioral-level description or register-transfer level (RTL) description of the hardware functionality in a high-level design language (HDL) such as Verilog or VHDL. The description may be read by a synthesis tool which may synthesize the description to produce a netlist including a list of gates from a synthesis library. The netlist includes a set of gates that also represent the functionality of the hardware including integrated circuits. The netlist may then be placed and routed to produce a data set describing geometric shapes to be applied to masks. The masks may then be used in various semiconductor fabrication steps to produce the integrated circuits. Alternatively, the database on the computer accessible storage medium may be the netlist (with or without the synthesis library) or the data set, as desired, or Graphic Data System (GDS) II data.

While particular embodiments have been described, various modifications to these embodiments will be apparent to those skilled in the art. For example, the embodiments have been described with reference to a soon-to-be standardized graphics double data rate (GDDR) design known as GDDR, version seven (GDDR7), but can also be applied to other memory types including non-graphics DDR memory, high-bandwidth memory (HBM), and the like. Moreover while they have been described with reference to a data processing system having a discrete GPU for very high performance graphics operations, they can also be applied to a data processing system with an accelerated processing unit (APU) in which the CPU and GPU are incorporated together on a single integrated circuit chip.

Accordingly, it is intended by the appended claims to cover all modifications of the disclosed embodiments that fall within the scope of the disclosed embodiments.

What is claimed is:

1. A data processing system comprising:
a data processor integrated circuit (IC) coupled to a substrate and including a physical layer circuit (PHY) for coupling to a memory over conductive traces on the substrate, the PHY comprising:
a reference clock generation circuit providing a reference clock signal to the memory;
a first group of driver circuits providing command/address (CA) signals to the memory; and
a second group of driver circuits providing data (DQ) signals to the memory; and
wherein a plurality of the conductive traces which carry the DQ signals are constructed with a length longer than that of conductive traces carrying the reference clock signal in order to reduce an effective insertion delay associated with coupling the reference clock signal to latch respective incoming DQ signals at the memory.

2. The data processing system of claim 1, wherein the longer length is sufficient to reduce the effective insertion delay at least 50 picoseconds as compared to an equal length.

3. The data processing system of claim 1, wherein the plurality of the conductive traces carrying the DQ signals are at least 12 mm longer than the conductive traces carrying the reference clock signal in order to reduce the effective insertion delay.

4. The data processing system of claim 1, wherein the reduced insertion delay reduces n-cycle accumulated jitter associated with the reference clock signal for at least some of a plurality of DQ receivers at the memory.

5. The data processing system of claim 1, wherein:
the memory includes a read clock driver providing a read clock signal to the data processor IC over a respective one of the conductive traces; and
a respective conductive trace carrying the read clock signal is shorter than that of conductive traces carrying the DQ signals.

6. The data processing system of claim 1, wherein the plurality of the conductive traces which carry the DQ signals are constructed to be longer than a potential shortest length path available for their routing along the substrate.

7. The data processing system of claim 1, wherein the substrate comprises a printed circuit board (PCB).

8. A method for signaling between a physical layer (PHY) circuit and a memory, comprising:
driving command/address (CA) signals to the memory over a first group of conductive traces on a substrate;
driving data (DQ) signals to the memory over a second group of conductive traces on the substrate; and
providing a reference clock signal to the memory over at least one additional conductive trace on the substrate having an associated propagation delay shorter than that of the second group of conductive traces in order to reduce an effective insertion delay associated with coupling the reference clock signal to latch respective incoming DQ signals.

9. The method of claim 8, wherein the effective insertion delay is reduced by at least 50 picoseconds.

10. The method of claim 8, further comprising forming a plurality of the conductive traces carrying the DQ signals to be at least 12 mm longer than those carrying the reference clock signal in order to reduce the effective insertion delay.

11. The method of claim 8, wherein the reduced insertion delay reduces n-cycle accumulated jitter associated with the reference clock signal for at least some of a plurality of DQ receivers at the memory.

12. The method of claim 8, further comprising driving a read clock signal from the memory over a respective one of the conductive traces having a length shorter than that of the conductive traces carrying the DQ signals.

13. The method of claim 8, further comprising providing the reference clock signal to the memory over the at least one additional conductive trace on the substrate having an associated propagation delay shorter than that of the first group of conductive traces in order to reduce an effective insertion delay associated with coupling the reference clock signal to latch respective incoming CA signals.

14. A memory system comprising:
a physical layer circuit (PHY) embodied on an integrated circuit, the PHY coupling to a memory over conductive traces on a substrate, the PHY comprising:
a reference clock generation circuit providing a reference clock signal to the memory;
a first group of driver circuits providing command/address (CA) signals to the memory; and
a second group of driver circuits providing data (DQ) signals to the memory; and
wherein a plurality of the conductive traces which carry the DQ signals are constructed with a length longer than that of conductive traces carrying the reference clock signal in order to reduce an effective insertion delay associated with coupling the reference clock signal to latch respective incoming DQ signals.

15. The memory system of claim 14, wherein the longer length is sufficient to reduce the effective insertion delay at least 50 picoseconds as compared to an equal length.

16. The memory system of claim 14, wherein the plurality of the conductive traces carrying the DQ signals are at least 12 mm longer than the conductive traces carrying the reference clock signal in order to reduce the effective insertion delay.

17. The memory system of claim 14, wherein the reduced insertion delay reduces n-cycle accumulated jitter associated with the reference clock signal for at least some of a plurality of DQ receivers at the memory.

18. The memory system of claim 14, wherein:
the memory includes a read clock driver providing a read clock signal to the data processor IC over a respective one of the conductive traces; and
a respective conductive trace carrying the read clock signal is shorter than that of conductive traces carrying the DQ signals.

19. The memory system of claim 14, wherein the plurality of the conductive traces which carry the DQ signals are constructed to be longer than a potential shortest length path available for their routing along the substrate.

20. The memory system of claim 14, wherein a plurality of the conductive traces which carry the CA signals are constructed with a length longer than that of conductive traces carrying the reference clock signal in order to reduce an effective insertion delay associated with coupling the reference clock signal to latch respective incoming CA signals.
